(19) United States
(12) Patent Application Publication
(10) Pub. No.: US 2024/0213382 A1
(43) Pub. Date: Jun. 27, 2024

(54) OPTOELECTRONIC SYSTEM COMPRISING A TRANSDUCER AND A WAVEGUIDE

(71) Applicant: COMMISSARIAT À L’ENERGIE ATOMIQUE ET AUX ENERGIES ALTERNATIVES, PARIS (FR)

(72) Inventors: Patrick LE MAITRE, GRENOBLE CEDEX 9 (FR); Fabian ROL, GRENOBLE CEDEX 9 (FR); Julia SIMON, GRENOBLE CEDEX 9 (FR); Nicolas MICHIT, GRENOBLE CEDEX 9 (FR)

(21) Appl. No.: 18/391,997

(22) Filed: Dec. 21, 2023

(30) Foreign Application Priority Data
Dec. 22, 2022 (FR) 2214261

(51) Int. Cl. H01L 31/0232; H01L 23/00; H01L 25/16; H01L 31/173; H01L 31/18; H01L 33/00; H01L 33/10; H01L 33/20

(52) U.S. Cl. CPC H01L 31/02327; H01L 24/08; H01L 24/29; H01L 24/32; H01L 24/80; H01L 24/83; H01L 25/167; H01L 31/173; H01L 31/1856; H01L 33/007; H01L 33/10; H01L 33/20; H01L 2224/08145; H01L 2224/29111; H01L 2224/29116; H01L 2224/29124; H01L 2224/29139; H01L 2224/29144; H01L 2224/29147; H01L 2224/29155; H01L 2224/29164; H01L 2224/29166; H01L 2224/29169; H01L 2224/29184; H01L 2224/29186; H01L 2224/32145; H01L 2224/80006; H01L 2224/80896; H01L 2224/83005; H01L 2924/0132; H01L 2924/04941; H01L 2924/04953; H01L 2924/0496

(57) ABSTRACT

An optoelectronic system includes a photoelectric transducer to emit or receive optical waves and a waveguide to guide waves emitted by the transducer or to guide waves to the transducer, includes a stack successively including a porous first layer of first type doped semiconductor material, a second layer of first type doped semiconductor material doped and lightly doped, a zone including quantum wells, a third layer of semiconductor material doped according to a second doping type opposite to the first type, the photoelectric transducer including a first portion of the porous first layer, a first portion of the second layer, at least a first portion of the zone including the quantum well(s) and at least a first portion of the third layer; the waveguide including a second portion of the second layer adjacent to the first portion and disposed on a second portion of the porous first layer.

### CROSS-REFERENCE TO RELATED APPLICATIONS

This application claims priority to French Patent Application No. 2214261, filed Dec. 22, 2022, the entire content of which is incorporated herein by reference in its entirety.

### FIELD

The technical field of the invention is that of photonic systems for intra-chip and inter-chip communication.

The present invention relates to an optoelectronic system comprising a waveguide and a photoelectric transducer, methods for manufacturing the optoelectronic system and methods for integrating the optoelectronic system with a control circuit.

### BACKGROUND

In the field of inter-chip or intra-chip communication, the use of optical signals and especially light to replace electrical signals makes it possible to overcome physical restrictions related to the impedance and size of metallic interconnections, and thus to meet the need to transfer large quantities of data at very high speed.

The photonic systems or platforms developed for this purpose comprise a light source, generally of micrometre dimensions, electrically excited and capable of being efficiently coupled to a photonic waveguide, which conducts the light and thus carries the information.

Within this context, light-emitting diode (LED) architectures, also called LED sources or micro-LED sources, have recently been used as light sources. Indeed, compared to laser sources, they have the advantage of being low-cost and low-power. It is also easier to reduce their dimensions down to the micrometre scale.

For example, LEDs make it possible to make free-field communications in the visible range. This is the principle behind LIFI (Light Fidelity), a technology for transmitting data at high speed in free fields by modulating the intensity of an LED lamp. Very recently, LEDs have also been used to emit light modulated in an optical fibre for short-distance interconnections (for example, distances of 10 metres).

New applications are emerging, especially for micro-LEDs, especially for high-speed, very low-power visible communications. A great deal of academic and industrial work is being done on the use of micro-LEDs at high frequencies (for example, 0.1 to 5 GHZ), both for transmission and reception.

However, the use of LED, especially micro-LED, sources poses the problem of efficiently coupling the emitted light into a waveguide.

In order to achieve good coupling of an LED, for example a GaN LED, into a waveguide, it is necessary to maximise the couplings between the light generated in the LED and the waveguide. This coupling is difficult because the LED emits optical modes in multiple directions.

In particular, by coupling an LED to a waveguide, it is possible to create a very short-distance, low-power inter-chip link. Other technologies could be contemplated, such as silicon photonics, which can provide very high data exchange rates over a same waveguide.

However, unlike the high-speed serial links possible in silicon photonics, communication using micro-LEDs does not require serialisation/deserialisation, which is very costly in terms of power consumption (the speed of a high-speed serial link being in the order of 25-50 Gbit/s, unlike communication with micro-LEDs where the speed of a link is in the order of a few Gbit/s) and space, and often requires very advanced CMOS technological nodes, below 30 nm, and external laser sources. Although InP laser sources can be bonded to a silicon substrate, this method is still complex and expensive, and reserved for some high-end applications.

There is therefore a need to maximise the coupling between an LED, especially a micro-LED, and a waveguide. More generally, there is a need to maximise the coupling between a photoelectric transducer and a waveguide.

### SUMMARY

An aspect of the invention offers a solution to the problems previously discussed, by maximising coupling between a photoelectric transducer (for example, an LED) and a waveguide.

A first aspect of the invention relates to an optoelectronic system including a photoelectric transducer configured to emit or receive optical waves and a waveguide configured to guide the waves emitted by the transducer or to guide the waves to the transducer,

said optoelectronic system including a stack successively comprising:
a porous first layer of semiconductor material doped according to a first doping type,
a second layer of semiconductor material doped according to the first doping type and lightly doped compared to the semiconductor material of the first layer,
a zone comprising one or more quantum wells,
a third layer of semiconductor material doped according to a second doping type opposite to the first doping type,
   the photoelectric transducer comprising a first portion of the porous first layer, a first portion of the second layer, at least a first portion of the zone comprising the quantum well(s) and at least a first portion of the third layer;
   the waveguide comprising a second portion of the second layer adjacent to the first portion and disposed on a second portion of the porous first layer.

Coupling between the transducer and the waveguide is improved by virtue of the second layer being common to the transducer and the waveguide. Indeed, the common second layer makes it possible to have the same refractive index in the transducer and the waveguide, and therefore to reduce number of photons reflected and lost. However, a waveguide only fulfils its function if an index contrast is possible between two materials. To achieve this index contrast, the porous first layer has been created in the transducer and extends under the waveguide to create an index contrast with the second layer which forms at least part of the waveguide. Thus, the optoelectronic system maximizes the coupling between the waveguide and the transducer by virtue of the common second layer and the porous first layer.

Further to the characteristics just discussed in the previous paragraph, the optoelectronic system according to the first aspect of the invention may have one or more additional characteristics from among the following, considered individually or according to any technically possible combinations:
the porous first layer has a porosity rate of between 1% and 80%. The effective index of the porous first layer depends on the porosification rate. Thus, it is possible to adjust the index of the first layer as a function of the porosification rate and to change the index contrast between the first layer and the second layer. In particular, a stronger index contrast minimises radiation losses in curvatures.
the waveguide further comprises a second portion of the zone comprising the quantum well(s). Having part of the waveguide aligned with the quantum wells of the transducer minimises coupling losses between the transducer and the waveguide by maximising the modal overlap between the two parts.
the waveguide further comprises a second portion of the third layer.
the first doping type is N doping and the second doping type is P doping or the first doping type is P doping and the second doping type is N doping.
the waveguide has a height of between 200 nm and 300 nm and a width of between 200 nm and 300 nm. Such heights and widths of the guide are adapted to obtain single-mode propagation in the visible range for the optical indices considered. Single-mode propagation is not essential, but is desirable in order to make passive or active photonic components, for example a power divider (or splitter) or a grating coupler, and to be able to propagate light in curved waveguides.
the first layer, the second layer and the third layer are formed of the same semiconductor material, for example a III-V material, for example gallium nitride.
the photoelectric transducer comprises a first electrode in electrical contact with the second layer and a second electrode in electrical contact with the third layer. Thus, the transducer differs from the waveguide especially in that it comprises electrodes. The first and second electrodes do not extend into the waveguide.
the photoelectric transducer is of the light-emitting diode or photodiode type.
the optoelectronic system comprises a dielectric layer coating the photoelectric transducer and the waveguide.
the optoelectronic system comprises a mirror disposed on at least one peripheral surface of the photoelectric transducer. The addition of a mirror and/or a dielectric layer on at least one peripheral surface of the transducer makes it possible to minimise losses to the substrate.
the optoelectronic system comprises a Bragg mirror arranged under the transducer and under the waveguide, said mirror comprising one or more porous layers of semiconductor material stacked alternately with one or more non-porous layers of semiconductor material. The Bragg mirror minimises optical losses to the substrate without having an impact/effect on the horizontal propagation of the waves.
the optoelectronic system comprises a second photoelectric transducer, the transducer and the second transducer being disposed on either side of the waveguide, and the second photoelectric transducer includes:
   a third portion of the porous first layer,
   a third portion of the second layer
   a third portion of the zone comprising the quantum well(s),
   a third portion of the third layer.
the second photoelectric transducer is of the light-emitting diode or photodiode type and of a type distinct from the photoelectric transducer.

A second aspect of the invention relates to a method for manufacturing the optoelectronic system according to the first aspect of the invention, the method comprising:
Forming a stack by successively epitaxially growing, on a substrate, a layer of semiconductor material doped according to the first doping type, the second layer of semiconductor material the zone comprising the quantum well(s), and the third layer of semiconductor material,
Porosifying the layer of semiconductor material doped according to the first doping type, to obtain the first porous semiconductor layer,
Partially etching at least the third layer of semiconductor material to delimit the waveguide and obtain a first non-etched patterned zone,
Partially etching the stack to the second layer of semiconductor material, so as to laterally delimit the transducer in the first patterned zone,

Further to the characteristics just discussed in the previous paragraph, the method according to the second aspect of the invention may have one or more additional characteristics from among the following, considered individually or according to any technically possible combinations:
the step of partially etching at least the third layer of semiconductor material is performed so as to further delimit a second, non-etched patterned zone, the first and second patterned zones being disposed on either side of the waveguide,
the step of partially etching the stack to the second layer of semiconductor material is performed so as to further delimit the second transducer laterally in the second patterned zone.
The method according to the second aspect of the invention comprises forming:
   a first electrode in electrical contact with the first portion of the third layer,
   a second electrode in electrical contact with the first portion of the second layer,
   a third electrode in electrical contact with the third portion of the third layer, and in an embodiment,
   a fourth electrode in electrical contact with the third portion of the second layer.

A third aspect of the invention relates to a method for manufacturing the optoelectronic system according to the first aspect of the invention, the method comprising:
forming a stack by successively epitaxially growing, on a substrate, a layer of semiconductor material doped according to the first doping type and the second layer of semiconductor material doped according to the first doping type and lightly doped compared to the first layer,
Partially etching the second layer of semiconductor material, so as to obtain an island,
Porosifying the layer of semiconductor material doped according to the first doping type, to obtain the first layer of porous semiconductor material,
Selectively epitaxially forming the zone comprising the quantum well(s) on a first region of the island,
Selectively epitaxially forming the third layer of semiconductor material on the zone comprising the quantum well(s) in the first region, so as to form the transducer in the first region,
According to an embodiment:
   the step of selectively epitaxially forming the zone comprising the quantum well(s) is performed simultaneously on a second region of the island, distinct from the first region,
   the step of selectively epitaxially forming the third layer of semiconductor material is performed simultaneously in the second region of the island so as to form the second transducer in the second region of the island,
the method according to the third aspect of the invention comprises forming:
   a first electrode in electrical contact with the first portion of the third layer and belonging to the transducer,
   a second electrode in electrical contact with the second layer, the second electrode being, in an embodiment, common to the transducer and the second transducer;
   a third electrode in contact with the third portion of the third layer and belonging to the second transducer.

A fourth aspect of the invention relates to a method for integrating an optoelectronic system according to the first aspect of the invention with an integrated control circuit, the method comprising:
forming a stack by successively epitaxially growing, on a substrate, a layer of semiconductor material doped according to the first doping type, the second layer, the zone comprising the quantum well(s), and the third layer of semiconductor material,
porosifying the layer of semiconductor material doped according to the first doping type, to obtain the first layer of porous semiconductor material,
partially etching at least the third layer, to delimit the waveguide and obtain a first patterned zone and a second patterned zone, the first patterned zone and the second patterned zone being disposed on either side of the waveguide,
depositing a dielectric layer onto the waveguide;
depositing a first metal layer onto the dielectric layer and the third layer in the first patterned zone and the second patterned zone,
depositing a second metal layer onto a first face of a receiving substrate, the receiving substrate comprising the control circuit,
bonding the first metal layer and the second metal layer,
removing the substrate,
partially etching the first patterned zone to delimit the transducer and the second patterned zone to delimit the second transducer,
forming:
   a first electrode on the first portion of the second layer,
   a second electrode on the third portion of the second layer,
   a third metal layer on a second opposite face of the receiving substrate, the third metal layer being connected to the second metal layer forming a third electrode common to the transducer and the second transducer.

A fifth aspect of the invention relates to a method for integrating an optoelectronic system according to the first aspect of the invention with a control circuit, the method comprising:
manufacturing the optoelectronic system according to the first aspect of the invention, by performing the steps of the manufacturing method according to the second or third aspect of the invention;
forming on the stack a hybrid bonding tier comprising a first electrode in electrical contact with the first portion of the third layer, the first electrode belonging to the transducer, and a second electrode in electrical contact with the third portion of the third layer, the second electrode belonging to the second transducer, the first and second electrodes being surrounded by a dielectric layer, so as to obtain a planar surface with the first and second electrodes;
hybridly bonding the stack to a receiving substrate including the control circuit, the control circuit including a plurality of connection pads surrounded by a dielectric layer, so that the first electrode and the second electrode are bonded to the connection pads of the control circuit, and so that the dielectric layer of the stack is bonded to the dielectric layer of the control circuit,
removing the substrate,
partially etching:
   Within the transducer: from the first portion of the porous first layer to the second layer, to obtain a first aperture,
   Within the second transducer: from the third portion of the porous first layer to the second layer, to obtain a second aperture;
forming a third electrode in the first and second apertures, the third electrode being common to the transducer and the second transducer, and connecting the third electrode to one of the connection pads of the control circuit.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 is a cross-section view of an embodiment of an optoelectronic system according to a first aspect of the invention,

FIG. 2 and FIG. 3 represent alternatives to the embodiment of FIG. 1,

FIG. 4 is a top view of the alternative of FIG. 3,

FIG. 5, FIG. 6, FIG. 7 and FIG. 8 represent other alternatives to the embodiment of FIG. 1,

FIG. 9 is a top view of an embodiment of the optoelectronic system,

FIG. 10a, FIG. 10b, FIG. 10c, FIG. 10d and FIG. 10e are steps of a method for manufacturing the optoelectronic system according to a second aspect of the invention.

FIG. 11a, FIG. 11b, FIG. 11c, FIG. 11d, FIG. 11e and FIG. 11f are steps of a method for manufacturing the optoelectronic system according to a third aspect of the invention.

FIG. 12a, FIG. 12b, FIG. 12c, FIG. 12d, FIG. 12e, FIG. 12f, FIG. 12g, FIG. 12h, FIG. 12i and FIG. 12j are steps of a method for integrating the optoelectronic system according to a fourth aspect of the invention.

FIG. 13a, FIG. 13b, FIG. 13c, FIG. 13d and FIG. 13e are steps of a method for integrating the optoelectronic system according to a fifth aspect of the invention.

### DETAILED DESCRIPTION

The figures are set forth by way of indicating and in no way limiting purposes of the invention.

A first aspect of the invention relates to an optoelectronic system.

FIG. 1 shows a schematic cross-section representation of a first embodiment of the optoelectronic system 1. The optoelectronic system 1 includes a photoelectric transducer 11, configured to emit or receive optical waves, and a waveguide 12 configured to guide waves emitted by the transducer 11 or to guide received waves to the transducer 11. The transducer 11 is for example a light-emitting diode or a photodiode.

The optoelectronic system 1 includes, in an embodiment on a substrate 14, a stack successively comprising: a porous first layer 111 of semiconductor material doped according to a first doping type, a second layer 112 of semiconductor material doped according to the first doping type and lightly doped compared to the semiconductor material of the first layer 111, a zone 113 comprising one or more quantum wells and a third layer 116 of semiconductor material doped according to a second doping type. However, the second layer 112 of semiconductor material is sufficiently doped to make a P-N junction.

The semiconductor material is, for example, a III-V semiconductor material or a II-VI semiconductor material.

A III-V semiconductor material is formed for example from a binary alloy such as boron nitride (BN), boron phosphide (BP), boron arsenide (BAs), aluminium nitride (AlN), aluminium phosphide (AIP), aluminium arsenide (AlAs), aluminium antimonide (AISb), gallium phosphide (GaP), gallium arsenide (GaAs), gallium antimonide (GaSb), indium nitride (InN), indium phosphide (InP), indium arsenide (InAs), indium antimonide (InSb) or for example gallium nitride (GaN). A III-V material may also be a semiconductor material formed from a ternary alloy such as gallium-indium nitride (InGaN), aluminium-gallium nitride (AlGaN), gallium-indium phosphide (InGaP), etc.

A II-VI semiconductor material is for example formed from cadmium telluride (CdTe) or cadmium sulphide (CdS). Beneficially, CdTe and CdS are efficient light-emitting semiconductors.

More generally, the semiconductor material forming each layer of the optoelectronic system 1 is capable of emitting light.

The substrate 14 may comprise a support layer, also referred to as a growth medium, for example formed of silicon or sapphire, and a buffer layer formed of, for example, gallium nitride and disposed on the support layer.

The first doping type (or conductivity type) is opposite to the second doping type. For example, the first doping type is N-type doping and the second doping type is P-type doping. Alternatively, the first doping type is P-type doping and the second doping type is N-type doping.

The photoelectric transducer 11 comprises a first portion 111a of the porous first layer 111, a first portion 112a of the second layer 112, a first portion 113a of the zone 113 comprising the quantum well(s) and a first portion 116a of the third layer 116.

The waveguide 12 comprises a second portion 112b of the second layer 112 adjacent to the first portion 112a and disposed on a second portion 111b of the porous first layer 111. In other words, the second layer 112 extends beyond the transducer 11 to form at least part of the waveguide 12. Furthermore, the first layer 111 extends beyond the transducer 11 and is disposed under the waveguide 12. In particular, the second portion 112b of the second layer 112 forms the core of the waveguide 12.

The first layer 111, the second layer 112 and the third layer 116 are beneficially formed of the same semiconductor material, for example gallium nitride (GaN). The same semiconductor material makes it easier to manufacture the optoelectronic system 1.

According to an embodiment, the third layer 116 is formed of P-doped GaN, the zone 113 comprises one or more InGaN/(GaN) quantum wells (emitting in the red, green or blue for example), the second layer 112 is formed of N-doped GaN and the first layer 111 is formed of heavily N-doped GaN.

The semiconductor material of the first layer 111 is heavily doped compared to the semiconductor material of the second layer 112. In other words, the concentration of dopant impurities in the first layer 111 is, for example, greater than or equal to 5 times the concentration of dopant impurities in the second layer 112. For example, the concentration of doping impurities in the first layer 111 is in the order of 10¹⁹ atoms/cm³ and the concentration of doping impurities in the second layer 112 is in the order of 10¹⁷ atoms/cm³.

The coupling between the transducer 11 and the waveguide is improved by virtue of the second layer extending continuously in the transducer 11 and in the waveguide 12. Indeed, the second layer 112 makes it possible to have the same refractive index in the transducer 11 and the waveguide 12. If the refractive index of the transducer 11 is different from the refractive index of the waveguide 12, light waves can be injected into the guide by the transducer, but a greater number of photons will be reflected (depending on the angles of incidence) and will therefore be lost.

However, a waveguide only fulfils its function if an index contrast is possible between two materials. This index contrast is obtained here between the porous first layer 111 and the second layer 112.

Let n₁₁₁ be the refractive index of the semiconductor material forming the porous first layer 111 and nₐᵢᵣ the index of air. The refractive index of the porous first layer 111 is equal to n_{eff}=[(1−φ)n₁₁₁²+φ nₐᵢᵣ²]1/2, with φ the porosity rate of the porous first layer 111.

In particular, φ is between 1% and 80%, for example between 20% and 80%, and in particular between 40% and 80% or between 20% and 70%. In particular, φ is in an embodiment equal to 20%. A degree of porosity equal to 20% makes it possible, for example, to obtain the waveguide 12 with an index contrast of 3 between the porous first layer 111 and the second layer 112.

The largest dimension (the height) of the pores of the first layer 111 can vary from a few nanometres to a few micrometres. The smallest dimension (the diameter) may vary from a few nanometres to a hundred nanometres, in particular from 10 nm to 70 nm, for example from 30 nm to 70 nm, and in an embodiment from 15 nm to 40 nm.

In the embodiment of FIG. 1, the height h of the waveguide 112 is equal to the thickness of the second layer, such as between 200 nm and 350 nm.

The transducer 11 further comprises a first electrode 117, in electrical contact with the first portion 116a of the third layer 116, and a second electrode (not represented in FIG. 1), in electrical contact with the first portion 112a of the second layer 112.

The first electrode 117 is in an embodiment disposed on the first portion 116a of the third layer 116 and in direct contact therewith. It may cover the entire upper face of the first portion 116a of the third layer 116, since vertical emission/reception of light is not desired.

Unlike the second layer 112, the first and second electrodes do not extend into the waveguide 12. The waveguide 12 is devoid of electrode.

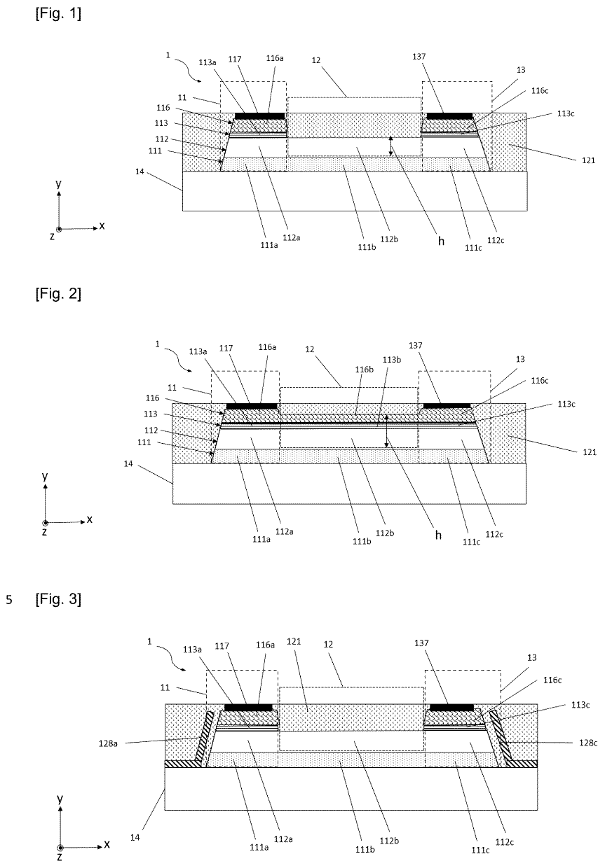

FIG. 2 represents an alternative to the embodiment of FIG. 1.

The waveguide 12 additionally comprises a second portion 113b of the zone 113 comprising the quantum well(s) and a second portion 116b of the third layer 116. The second portion 116b of the third layer 116 may be thinned, that is, have a thickness less than that of the first portion 116a of the third layer 116.

Thus, the zone 113 comprising the quantum well(s) extends beyond the transducer 11 to form part of the waveguide 12 and the third layer 116 extends beyond the transducer 11 to also form part of the waveguide 12.

This has the effect of further improving the coupling between the transducer 11 and the waveguide 12, as the modal overlap between the guide and transducer portion is improved.

The quantum wells in the waveguide absorb only a negligible part of the light, by virtue of the Stokes shift, which translates the wavelength offset between the absorption peak and the emission peak (the absorption wavelength is smaller than the emission wavelength). By decreasing the size of the waveguide 12 in height and width (to head towards single-mode propagation), the mechanical stresses and the inner electric field are decreased, which increases the Stokes shift. The height is defined along the axis y, and the width along the axis z.

In this alternative embodiment, the height h of the waveguide is in an embodiment between 200 nm and 300 nm.

According to an alternative of FIG. 1 not represented, the waveguide comprises, in addition to the second portion 112b of the second layer 112, only the second portion 113b of the zone 113 comprising the quantum well(s).

In a manner common to all the embodiments and alternatives, the optoelectronic system 1 may comprise a second photoelectric transducer 13, configured to emit or receive optical waves, the waveguide 12 also being configured to guide the waves emitted by the second transducer 13 or to guide the waves to the second transducer 13. The second transducer 13 is for example a light-emitting diode or a photodiode.

In an embodiment, the second transducer 13 is of a different type from the transducer 11. The type refers to the emitting or receiving nature of the transducer, that is, light-emitting diode or photodiode. Thus, one of the transducers 11 and 13 is in emission mode (LED) and the other of the transducers 11 and 13 is in reception mode (photodiode).

The second transducer 13 comprises a third portion 111c of the porous first layer 111, that is, the porous first layer 111 extends beyond the first transducer 11 and the waveguide 12 to form part of the second transducer 13.

The second transducer further comprises a third portion 112c of the second layer 112, that is, the second layer 112 extends beyond the first transducer 11 and the waveguide 12 to form part of the second transducer 13.

The second transducer 13 comprises a third portion 113c of the zone 113 comprising the quantum well(s) and a third portion 116c of the third layer 116.

In the embodiment of FIG. 1, the third portion 113c of the zone 113 is distinct (that is, separate) from the first portion 113a of the zone 113 and the third portion 112c of the second layer 112 is distinct from the first portion 112a of the second layer 112. Conversely, in the alternative of FIG. 2, the second portion 113b of the zone 113 is adjacent to the first and third portions 113a and 113c of the zone 113 and the second portion 112b of the second layer 112 is adjacent to the first and third portions 112a and 112c of the second layer 112.

The second transducer 13 further comprises a third electrode 137 in electrical contact with the third portion 116c of the third layer 116. The third electrode 137 is in an embodiment disposed on and in direct contact with the third portion 116c of the third layer 116.

In the absence of the second transducer 13, the transducer 11 may comprise the entire zone 113 and the entire third layer 116.

The optoelectronic system 1 may further comprise a dielectric layer 121 coating the transducer 11, the waveguide 12 and, where appropriate, the second transducer 13. The dielectric layer 121 forms, in an embodiment, a planar surface with the electrodes 117, 137 of the transducer 11 and the second transducer 13. The dielectric layer 121 is for example formed of aluminium oxide (or alumina, Al₂O₃).

According to an embodiment represented in FIG. 3, the optoelectronic system 1 comprises a first mirror, or reflective structure 128a located on one or more peripheral surfaces of the transducer 11 and, where appropriate, a second mirror 128c located on one or more peripheral surfaces of the second transducer 13. In an embodiment, the first and second mirrors 128a-128c are each formed of a metal layer. The two metal layers are formed of, in an embodiment, the same metal, for example aluminium.

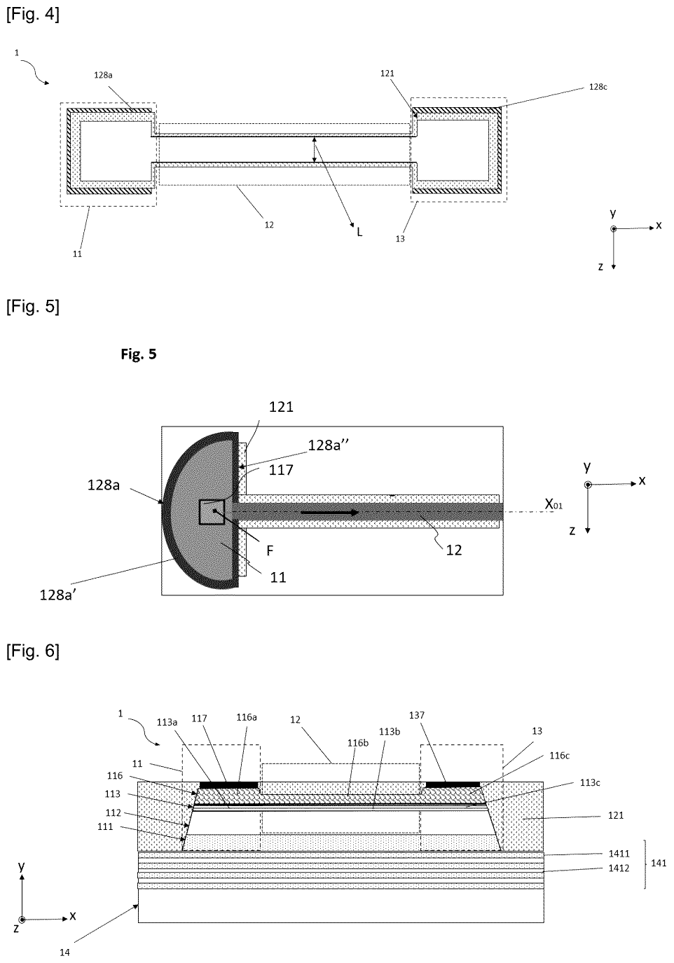

FIG. 4 is a top view of the optoelectronic system 1 according to FIG. 3. This figure shows the dielectric layer 121 surrounding the transducer 11, the waveguide 12 and the second transducer 13, the first mirror 128a disposed on several lateral faces of the transducer 11 and separated therefrom by the dielectric layer 121, and the second mirror 128c disposed on several lateral faces of the second transducer 13 and separated therefrom by the dielectric layer 121.

The arrangement of the dielectric layer 121, the first mirror 128a and, where appropriate, the second mirror 128c promotes coupling of the light from the transducers into the waveguide (in the case of an LED type transducer) and/or the reception of the light by the other transducer (in the case of a photodiode type transducer) by reducing the losses of light rays.

Still with reference to FIG. 4, the width L (defined along the axis z) of the waveguide 12 (without the dielectric layer 121) is in an embodiment less than the width of the transducer 11 (and the width of the second transducer 13), for example between 200 nm and 300 nm.

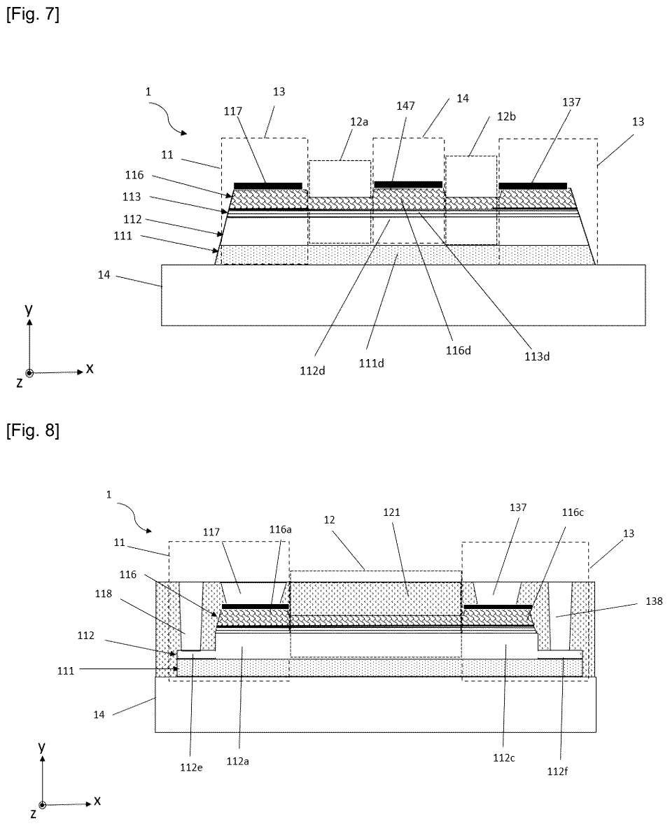

In an alternative embodiment represented by FIG. 5, the first mirror 128a is parabolic-cylindrical in shape with an axis y. The transducer 11 (comprising the stack of layers) fits the shape of the first mirror 128a and therefore has a first lateral surface that is also parabolic-cylindrical in shape. The first electrode 117 of the transducer 11 is located vertically to at least some of the foci F of the first mirror 128a. In particular, the first mirror 128a is a truncated right cylinder, with axis and generatrices perpendicular to the plane (X, Z) of the substrate 14, and assuming as its directrix curve a parabola of axis X₀₁ parallel to the plane of the substrate 10 and having as its focus the point F located on the axis X₀₁, the right cylinder being truncated by a plane parallel to the generatrices and passing through the focus F. The first mirror 128a is thus delimited by a cylindrical surface comprising a parabolic lateral surface 128a′ and a planar lateral surface 128a″.

The dielectric layer 121 which coats the waveguide 12 covers at least a second lateral surface opposite to the first mirror 128a. It may also extend, as previously described, between the transducer 11 and the first mirror 128a, as previously described in relation to FIG. 4.

Thus, when the transducer 11 is an LED, the waves emitted by the transducer 11 and received by the first mirror 128a are concentrated in the waveguide 12. Conversely, when the transducer 11 is a photodiode, the waves coming from the waveguide 12 and received by the first mirror 128a are concentrated in the transducer 11.

FIG. 6 is an alternative embodiment of the optoelectronic system 1 wherein the substrate 14 comprises a Bragg mirror 141, for example directly in contact with the porous first layer 111. In particular, the Bragg mirror 141 (otherwise referred to as a porous mirror) comprises one or more porous layers 1411 of semiconductor material stacked alternately with one or more non-porous layers 1412 of semiconductor material. When the transducer 11 is a light-emitting diode, the Bragg mirror 141 minimises losses to the substrate 14, without having an impact on the propagation of light in the waveguide 12.

FIG. 7 is an alternative embodiment of the optoelectronic system 1 wherein the optoelectronic system 1 comprises a third transducer 14 and wherein the waveguide 12 comprises a first portion 12a and a second portion 12b disposed on either side of the third transducer 14. In particular, the third transducer 14 comprises a fourth portion 111d of the first layer 111, a fourth portion 112d of the second layer 112, a fourth portion 113d of the zone 113 comprising the quantum well(s) and a fourth portion 116d of the third layer 116. Further, the third transducer 14 comprises an electrode 147 disposed on the fourth portion 116d of the third layer 116. The electrode 147 of the third transducer 14 does not extend beyond the third transducer 14.

The third transducer 14 is in an embodiment a light-emitting diode located in the optical path of the waves guided by the waveguide 12. Its role is to change the wave propagation index or to modulate power of said waves (modulator function), by applying bias which makes it possible to absorb light propagating in the waveguide 12 and passing through the third transducer 14.

FIG. 8 shows a possible arrangement of the electrodes of the optoelectronic system 1, compatible with all the embodiments previously described.

In addition to the first electrode 117 disposed on the first portion 116a of the third layer 116, the transducer 11 comprises a second electrode 118 disposed on a first recessed portion 112e of the second layer 112. The first recessed portion 112e is adjacent to the first portion 112a.

Furthermore, in addition to the third electrode 137 disposed on the third portion 116c of the third layer 116, the second transducer 13 may comprise a fourth electrode 138 disposed on a second recessed portion 112f of the second layer 112. The second recessed portion 112f is adjacent to the third portion 112c.

The fourth electrode 138 is not mandatory, since electrical contact with the second layer 112 is already ensured by the second electrode 118 and the second layer 112 extends continuously to the second transducer 13. However, it improves current distribution in the second transducer (also referred to as electrical injection in the case of an LED).

The first and second recessed portions 112e-112f of the second layer 112 are in an embodiment formed by partially etching the second layer 112.

In an embodiment, none of the electrodes extend beyond the transducer 11 or beyond the second transducer 13 in the waveguide 12.

When the second layer 112 is N-doped and the third layer 116 is P-doped, the first electrode 117 is the anode of the transducer 11, the second electrode 118 is the cathode of the transducer 11, the third electrode 137 is the cathode of the second transducer 13 and the fourth electrode 138 is the anode of the second transducer 13.

According to another arrangement, the second electrode 118 and/or the fourth electrode 138 is disposed in contact with a lower face of the second layer 112 and consequently extends through the porous first layer 111.

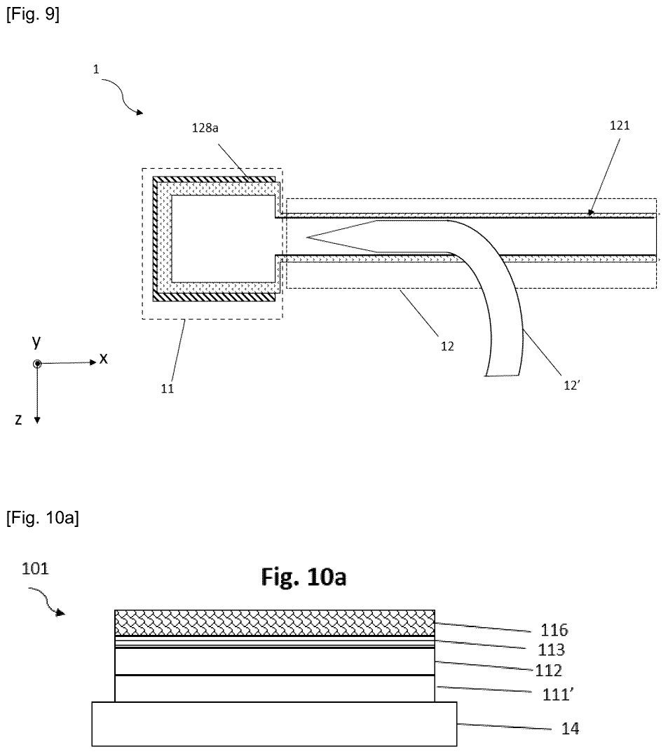

FIG. 9 represents in a top view another embodiment of the optoelectronic system 1 wherein a second waveguide 12′ is coupled to the first waveguide 12, for example by evanescent coupling. The second waveguide is in an embodiment made of SiN, AlN or Al₂O₃ and makes it possible, for example, to propagate the light waves emitted by the transducer 11 and propagating in the waveguide 12. The second guide 12′, which extends perpendicularly to the first guide 12, for example, propagates the waves with fewer losses than the first guide 12. The evanescent coupling causes few losses.

A second aspect of the invention relates to a method 100 for manufacturing the optoelectronic system 1 according to the first aspect of the invention.

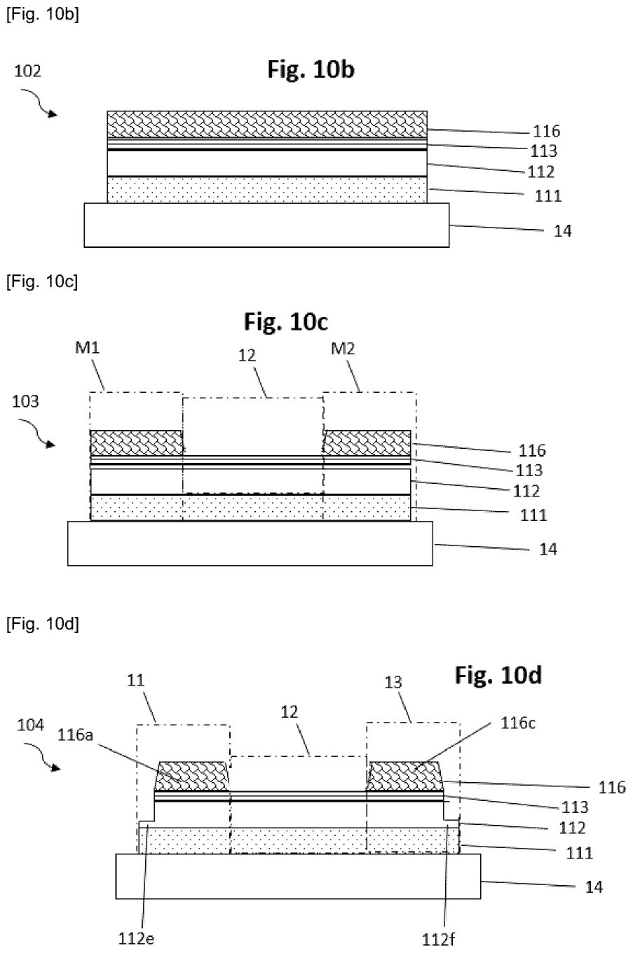

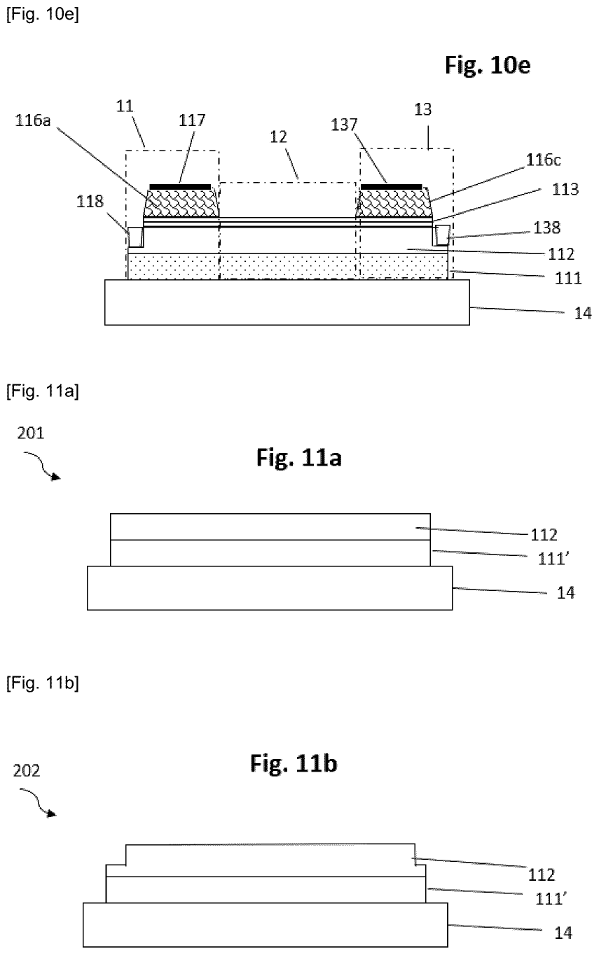

A first step 101 of the method 100, represented in FIG. 10a, is a step of forming a stack, by successively epitaxially growing on the substrate 14 a layer 111′ of semiconductor material heavily doped according to the first doping type, the second layer 112 of semiconductor material, the zone 113 comprising the quantum well(s), and the third layer 116 of semiconductor material.

A second step 102 of the method 100, represented in FIG. 10b, is a step of porosifying the layer 111′ to obtain the porous first layer 111. Porosification is performed, for example, by an electrochemical method: the layer 111′ is dipped in a solution and a potential difference is applied between the layer 111′ and the solution, which results in the formation of pores in the layer 111′. During porosification, the heavily doped layer 111′ acts as the anode and a platinum wire can act as the cathode. Porosification, known as electrochemical porosification, is for example carried out in an oxalic acid solution (0.2M) by applying a voltage of 15V for 30 min,

A third step 103 of the method 100, represented in FIG. 10c, is a step of partially etching at least the third layer 116, to delimit the waveguide 12, and to obtain a first non-etched patterned zone M1.

In an embodiment, the third layer 116 can be etched over its entire thickness, thus to the zone 113 comprising the quantum well(s) to form the first portion 116a and the third portion 116c of the third layer 116, the layer 116c not being formed in this case. This embodiment makes it possible to electrically insulate the first patterned zone M1 and the second patterned zone M2 to the small quantum well. In particular, the thickness of the zone 13 comprising one or more quantum wells is equal or substantially equal to 100 nm.

The third layer 116 may also be etched over only part of its thickness, to form the first portion 116a, the second portion 116b and the third portion 116c.

The zone 113 comprising the quantum well(s) may also be etched, following the third layer 116 (according to the desired composition of the waveguide 12).

As represented by FIG. 10d, the step of partially etching at least the third layer 116 may further delimit an unetched second patterned zone M2, the first and second patterned zones M1, M2 being disposed on either side of the waveguide 12.

At the end of step 103, the first portion 116a and the third portion 116c of the third layer 116 are obtained.

A fourth step 104 of the method 100 is a step 104 of partially etching the stack to the second layer 112, so as to laterally delimit the transducer 11 in the first patterned zone M1. In an embodiment, the first recessed portion 112e of the second layer 112 is formed simultaneously.

When the patterned zone M2 has been delimited in the third step 103, the etching of the stack performed in the fourth step 104 may further delimit, laterally, the second transducer 13 in the second patterned zone M2. The second recessed portion 112f of the second layer 112 is in an embodiment formed simultaneously.

A fifth step 105 of the method, represented in FIG. 10e, is a step of forming the first electrode 117 and the second electrode 118 of the transducer 11. The third electrode 137 and the fourth electrode 138 of the second transducer 13 may also be formed during this fifth step 105. The electrodes 117-118, 137-138 are as described with reference to FIG. 8.

The second step 102 of porosifying the layer 111′ of heavily doped semiconductor material may be carried out before or after the third 103 and fourth 104 steps of the method 100. Porosification may also be performed immediately after the growth of the layer 111′ of heavily doped semiconductor material, prior to the growth of the other layers of the stack.

A third aspect of the invention relates to a method 200 for manufacturing the optoelectronic system 1 according to the first aspect of the invention.

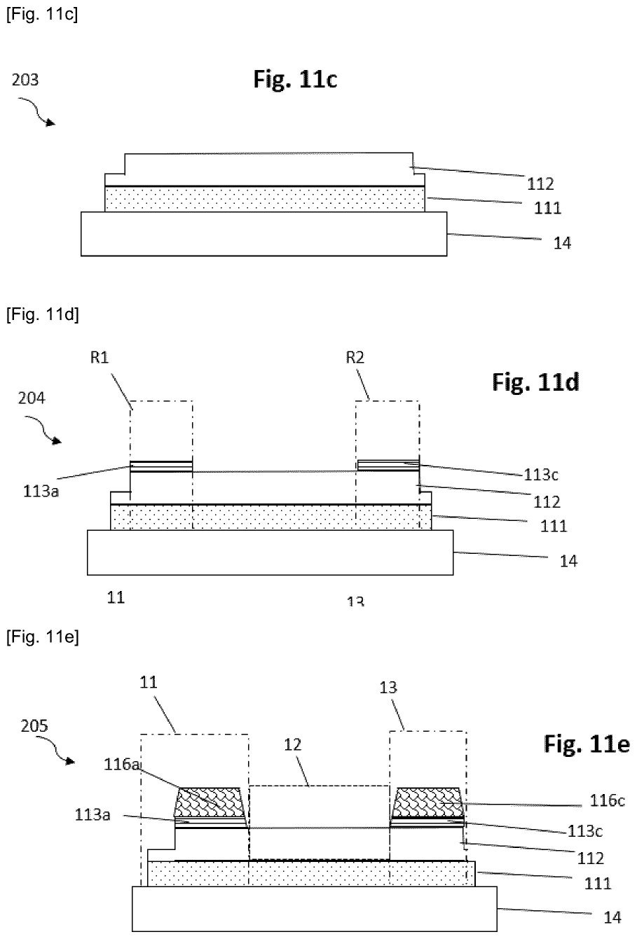

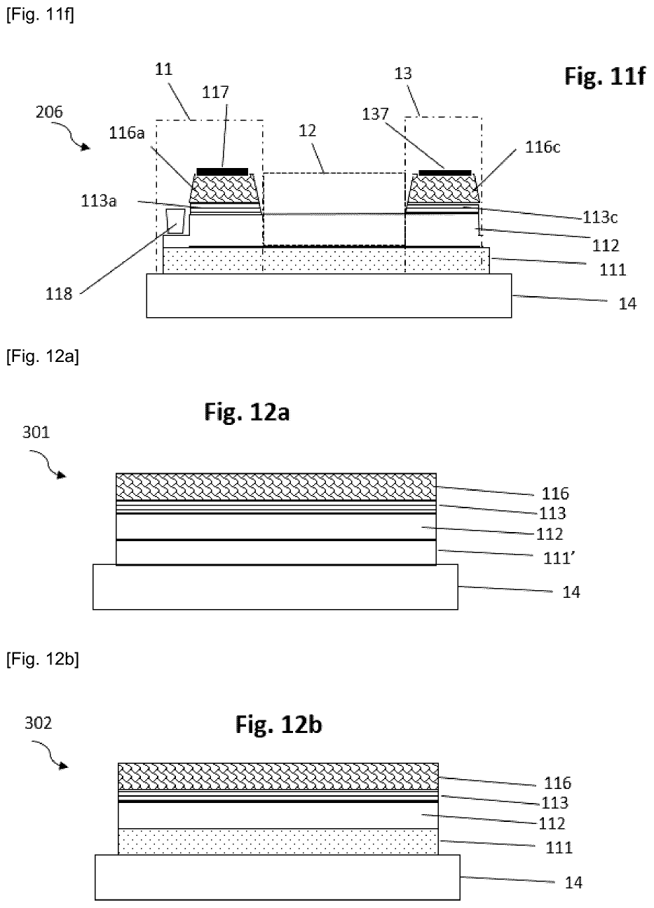

A first step 201 of the method 200, represented in FIG. 11a, is a step of forming a stack, on the substrate 14, by successively epitaxially growing a layer 111′ of semiconductor material doped according to the first doping type and the second layer 112 of semiconductor material doped according to the first doping type and lightly doped compared to the first layer 111.

A second step 202 of the method 200, represented in FIG. 11b, is a step of partially etching the second layer 112, so as to obtain an island (also called a “mesa”). Etching is used especially to define the mark that will be used to form an electrode, but also to form the mesa that passes through the 111′ layer so that it can then be porosified, otherwise the electrolyte enabling porosification has no access to the layer 111′.

A third step 203 of the method 200, represented in FIG. 11c is a step of porosifying the layer 111′ of conductive material doped according to the first doping type to obtain the porous first layer 111. In particular, the third step 203 of the method is performed identically to the second porosification step 102 of the method 100 according to the second aspect of the invention.

A fourth step 204 of the method 200, represented in FIG. 11d, is a step of selectively epitaxially forming the zone 113 comprising the quantum well(s) on a first region R1 of the island. In particular, the fourth step 204 makes it possible to form the first portion 113a of the zone 113.

According to an embodiment, the fourth step 204 is performed simultaneously on a second region R2 of the island, distinct from the first region R1. The third portion 113c of the zone 113 is thus formed.

In particular, the region R1 and the region R2 have been delimited by a hard mask to allow the first portion 113a and the third portion 113c of the zone 113 to be selectively epitaxially grown.

A fifth step 205 of the method 200, represented in FIG. 11e, is a step of forming the third layer 116 of semiconductor material on the zone 113 comprising the quantum well(s) in the first region R1, so as to form the transducer 11 in the first region R1. In particular, the fifth step 205 makes it possible to form the first portion 116a of the third layer 116.

According to an embodiment, the fifth step 205 of selectively epitaxially forming the third layer 116 of semiconductor material is performed simultaneously in the second region R2 of the island so as to form the third portion 116c of the third layer 116 and thus form the second transducer 13 in the second region R2 of the island.

A sixth step 206 of the method 206, represented in FIG. 11f, is a step of forming a first electrode 117 on the first portion 116a of the third layer 116, a second electrode 118 on a recessed portion of the second layer 112 (outside the island) and a third electrode 137 on the third portion 116c of the third layer 116.

The first electrode 117 is in electrical contact with the first portion 116a of the third layer 116 and thus belongs to the transducer 11, whereas the third electrode 137′ is in electrical contact with the third portion 116c of the third layer 116 and thus belongs to the second transducer 13.

The second electrode 118 is common here to the transducer 11 and to the second transducer 13. Alternatively, the method 200 may comprise, in the sixth step 206, forming a fourth electrode 138 in electrical contact with the second layer 112, on a recessed second portion of the second layer 112 (outside the island).

A fourth aspect of the invention relates to a method 400 for integrating an optoelectronic system 1 according to the first aspect of the invention with a control circuit for the transducers (LEDs and photodiodes). The control circuit is, for example, of the ASIC (application-specific integrated circuit) type.

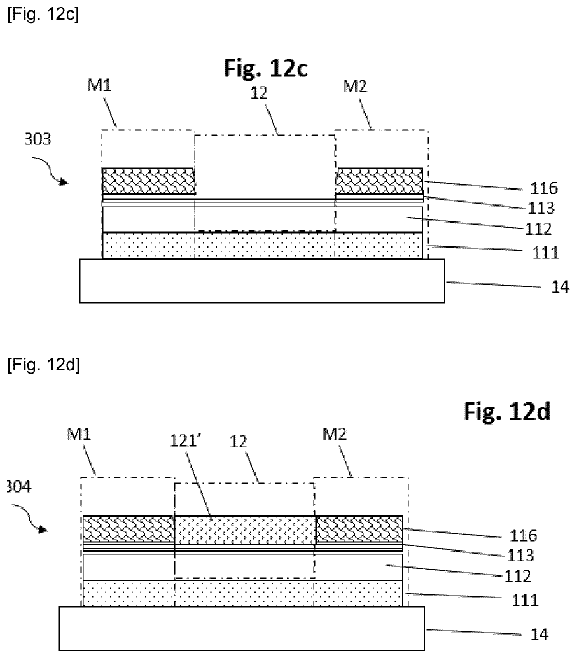

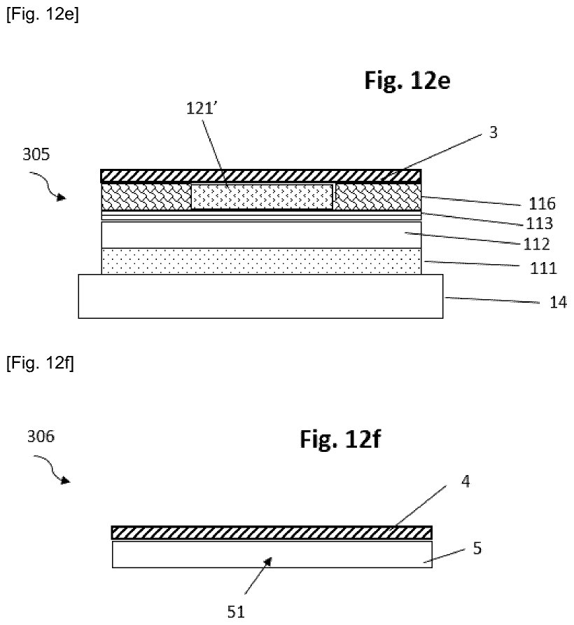

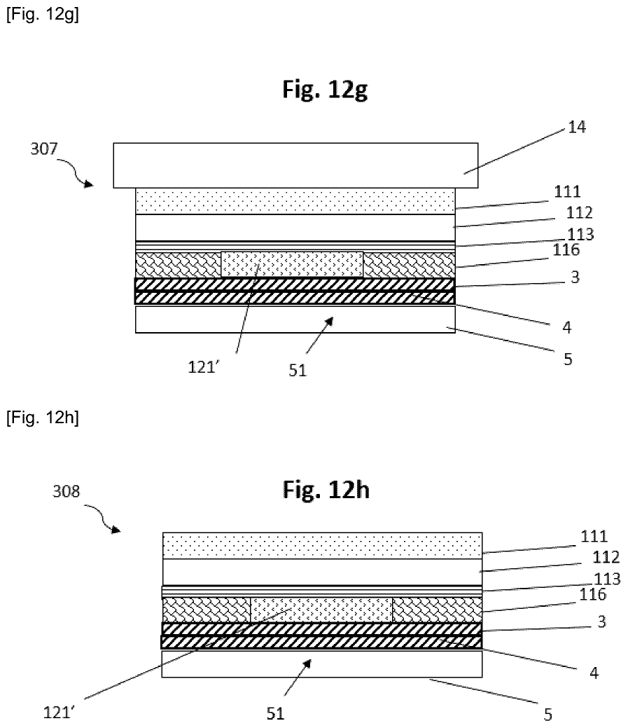

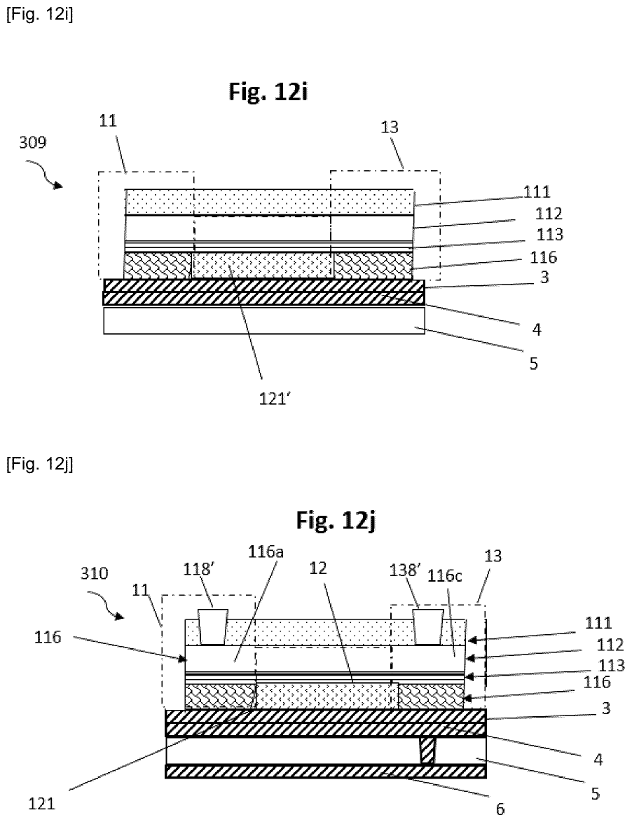

The first three steps 301 to 303 of the method 300, represented by FIG. 12a, FIG. 12a and FIG. 12c are identical to steps 101 to 103 of the method 100 (FIGS. 10a-10c).

A fourth step 304 of the method 300, represented in FIG. 12d, is a step of depositing a dielectric layer 121′ onto the waveguide 12.

A fifth step 305 of the method 300, represented in FIG. 12e, is a step of depositing a first metal layer 3 onto the dielectric layer 121′ and the third layer 116 into the first patterned zone M1 and the second patterned zone M2. The first metal layer 3 thus forms a first electrode (anode or cathode according to the doping type of the third layer 116) common between the transducer 11 and the second transducer 13.

The first metal layer 3 may comprise a first so-called barrier sublayer made of TaN, TIN, WN, TiW, or a combination of one or more of these materials and a second so-called bonding sublayer made of Ti, Ni, Pt, Sn, Au, Ag, Al, Pd, W, Pb, Cu, AuSn, TiSn, NiSn or an alloy of all or some of these materials. The barrier sublayer is disposed on the dielectric layer 121′ and the third layer 116, and the bonding sublayer is disposed on the barrier sublayer.

A sixth step 306 of the method 300, represented in FIG. 12f, is a step of depositing a second metal layer 4 onto a first face of a receiving substrate 5, the receiving substrate 5 comprising a control circuit 51. The control circuit 51 may especially include a plurality of connection pads (not represented) electrically connected to the second metal layer 4.

By way of example, the receiving substrate 5 is said to be “active”, that is, the substrate 5 comprises active electronic components such as transistors. The substrate 5 is, for example, of the CMOS type (Complementary Metal-Oxide-Semiconductor) or of the TFT type (Thin-Film Transistor).

Like the first metal layer 3, the second metal layer 4 may comprise a barrier sublayer made of TaN, TIN, WN, TiW, or a combination of one or more of these materials and a bonding sublayer made of Ti, Ni, Pt, Sn, Au, Ag, Al, Pd, W, Pb, Cu, AuSn, TiSn, NiSn or an alloy of all or some of these materials.

A seventh step 307 of the method 300, represented in FIG. 12g, is a step of bonding the first metal layer 3 and the second metal layer 4, so that the third layer 116 of the stack is electrically connected to the control circuit 51. Metal-to-metal bonding makes it possible to dispense with a step of precise alignment between the connection pads of the control circuit 51 and the transducers 11, 13 during the step of assembling the optoelectronic system 1 with the control circuit 51, this alignment step being generally difficult to perform, especially for transducers whose dimensions are less than 1 μm.

The bonding is, for example, molecular bonding, thermocompression bonding, eutectic bonding, or any other adapted fixing method.

An eighth step 308 of the method 300, represented in FIG. 12h, is a step of removing 308 the substrate 14, the removal being carried out by etching or chemical mechanical polishing (CMP) for example.

A ninth step 309 of the method 300, represented in FIG. 12i, is a step of partially etching the first zone of patterns M1 so as to laterally delimit the transducer 11 and of the second zone of patterns M2 so as to laterally delimit the second transducer 12. Completion of the ninth etching step 309 after the seventh bonding step 307 makes it possible to define a common electrode for the transducer 11 and the second transducer 13, said common electrode being formed by the first metal layer 3 and the second metal layer 4, the individual driving of each of the transducers among the transducer 11 and the second transducer 13 being carried out by the electrode 118′ for the transducer 11 and the electrode 138′ for the second transducer 13.

A tenth step 310 of the method 300, represented in FIG. 12j, is a step of forming a second electrode 118′ and a third electrode 138′ in electrical contact with the third layer 116 and a third metal layer 6 on a second opposite face of the receiving substrate 5.

The first electrode 118′ extends through the first portion 111a of the porous first layer 111 and belongs to the transducer 11.

The second electrode 138′ extends through the third portion 111c of the porous first layer 111 and belongs to the second transducer 13.

The third metal layer 6 is electrically connected to the second metal layer 4 by one or more vias passing through the receiving substrate 5.

A fifth aspect of the invention relates to a method 400 for integrating the optoelectronic system 1 according to the first aspect of the invention with a control circuit.

The method 400 for integrating the optoelectronic system 1 begins by manufacturing the optoelectronic system 1 comprising the transducer 11, the waveguide 12 and the second transducer 13. To this end, steps 101 to 104 of the manufacturing method 100 or steps 201 to 205 of the manufacturing method 200 are beneficially performed.

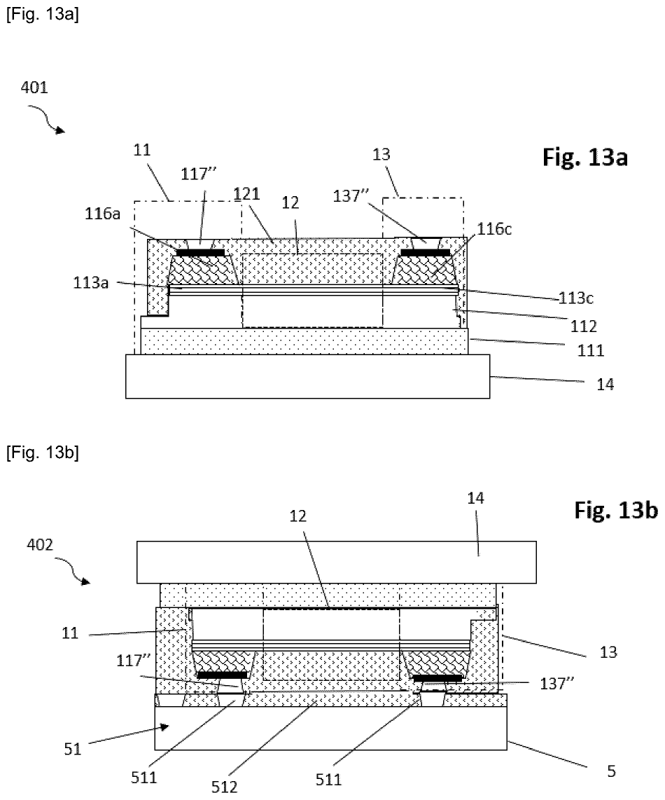

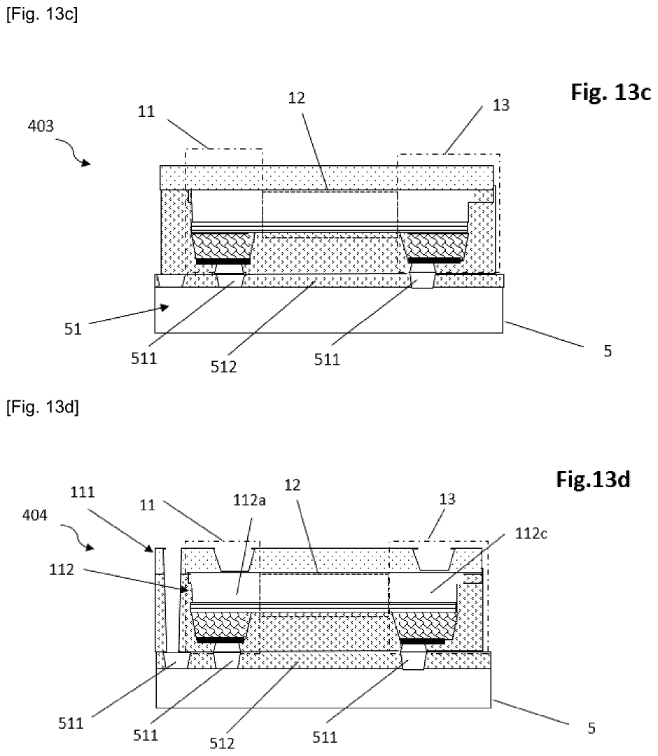

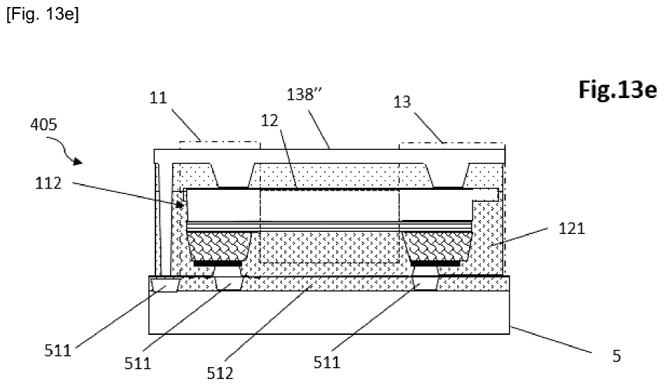

With reference to FIG. 13a, the method 400 then comprises a step 401 of forming a hybrid (metal-dielectric) bonding tier on the stack, and more particularly the waveguide 12 and the third layer 116. The hybrid bonding tier comprises a first electrode 117″ in electrical contact with the first portion 116a of the third layer 116 and a second electrode 137″ in contact with the third portion 116c of the third layer 116.

The hybrid bonding tier also comprises a dielectric layer 121 surrounding the first electrode 117″ and the second electrode 137″. The dielectric layer 121 forms a planar surface with the upper face of the first and second electrodes 117″, 137″.

With reference to FIG. 13b, the method 400 then comprises a step 402 of hybridly bonding the stack to a receiving substrate 5 comprising the control circuit 51.

In particular, the receiving substrate 5 includes a plurality of connection pads 511 surrounded by a dielectric layer 512. The first electrode 117″ and the second electrode 137″ are brought in contact with and bonded to the connection pads 511 of the control circuit, and the dielectric layer 121 of the stack is disposed in contact with and bonded to the dielectric layer 512 covering the receiving substrate 5.

With reference to FIG. 13c, the method 400 then comprises a step 403 of removing the substrate 14, by etching or CMP for example.

With reference to FIG. 13d, the method 400 then comprises a step 404 of partially etching the porous first layer 111, so as to obtain a first aperture which opens onto the first portion 112a of the second layer 112 (thus into the transducer 11) and a second aperture which opens onto the third portion 112c of the second layer 112 (thus into the second transducer 13).

Finally, FIG. 13e represents a step 405 of forming a third electrode 138″ in the first and second apertures and on the porous first layer 111, in an embodiment by deposition of a metal, the electrode 138″ thus being common to the transducer 11 and the second transducer 13.

The third electrode 138″ is beneficially connected to a metal pad 511 of the control circuit 51. This connection is beneficially made by forming a third aperture which extends through the porous first layer 111 and the dielectric layer 121 coating the transducer 11, the waveguide 12 and the second transducer 13, then by filling this third aperture with the metal.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations.

1. An optoelectronic system including a photoelectric transducer configured to emit or receive optical waves and a waveguide configured to guide the waves emitted by the photoelectric transducer or to guide the waves to the photoelectric transducer, said optoelectronic system including a stack successively comprising:
a porous first layer of semiconductor material doped according to a first doping type,
a second layer of semiconductor material doped according to the first doping type and lightly doped compared to the semiconductor material of the first layer,
a zone comprising one or more quantum wells,
a third layer of semiconductor material doped according to a second doping type opposite to the first doping type,
the photoelectric transducer comprising a first portion of the porous first layer, a first portion of the second layer, at least a first portion of the zone comprising the one or more quantum wells and at least a first portion of the third layer;
the waveguide comprising a second portion of the second layer adjacent to the first portion and disposed on a second portion of the porous first layer.

2. The optoelectronic system according to claim 1, wherein the porous first layer has a porosity rate of between 1% and 80%.

3. The optoelectronic system according to claim 2, wherein the waveguide further comprises a second portion of the zone comprising the one or more quantum wells.

4. The optoelectronic system according to claim 3, wherein the waveguide further comprises a second portion of the third layer.

5. The optoelectronic system according to claim 1, wherein the waveguide has a height of between 200 nm and 300 nm and a width of between 200 nm and 300 nm.

6. The optoelectronic system according to claim 1, wherein the first layer, the second layer and the third layer are formed of a same semiconductor material.

7. The optoelectronic system according to claim 1, wherein the photoelectric transducer is of a light emitting diode transducer or a photodiode transducer.

8. The optoelectronic system according to claim 1, further comprising a dielectric layer coating the photoelectric transducer and the waveguide.

9. The optoelectronic system according to claim 1, further comprising a mirror disposed on at least one peripheral surface of the photoelectric transducer.

10. The optoelectronic system according to claim 1, further comprising a Bragg mirror arranged under the photoelectric transducer and under the waveguide, said Bragg mirror comprising one or more porous layers of semiconductor material stacked alternately with one or more non-porous layers of semiconductor material.

11. The optoelectronic system according to claim 1, comprising a second photoelectric transducer, the photoelectric transducer and the second photoelectric transducer being disposed on either side of the waveguide, and wherein the second photoelectric transducer includes:
a third portion of the porous first layer,
a third portion of the second layer,
a third portion of the zone comprising the one or more quantum wells, a third portion of the third layer.

12. The optoelectronic system according to claim 11, wherein the second photoelectric transducer is a light emitting diode transducer or a photodiode transducer and of a type distinct from the first photoelectric transducer.

13. A method for manufacturing the optoelectronic system according to claim 12, comprising:
forming a stack by successively epitaxially growing, on a substrate, a layer of semiconductor material doped according to the first doping type, the second layer of semiconductor material, the zone comprising the one or more quantum wells, and the third layer of semiconductor material,
porosifying the layer of semiconductor material doped according to the first doping type, to obtain the porous first layer of semiconductor,
partially etching at least the third layer of semiconductor material, to delimit the waveguide, and obtain a first non-etched patterned zone, and
partially etching the stack to the second layer of semiconductor material, so as to laterally delimit the photoelectric transducer in the first patterned zone.

14. The method according to claim 13, wherein:
the step of partially etching at least the third layer of semiconductor material is performed so as to further delimit a second, non-etched patterned zone, the first and second patterned zones being disposed on either side of the waveguide,
the step of partially etching the stack to the second layer of semiconductor material is performed so as to further laterally delimit the second photoelectric transducer in the second patterned zone.

15. The method according to claim 13, comprising forming:
a first electrode in electrical contact with the first portion of the third layer, a second electrode in electrical contact with the first portion of the second layer,
a third electrode in electrical contact with the third portion of the third layer, and optionally,
a fourth electrode in electrical contact with the third portion of the second layer.

16. A method for manufacturing an optoelectronic system, the optoelectronic system being according to claim 1, the method comprising:
forming a stack by successively epitaxially growing, on a substrate, a layer of semiconductor material doped according to the first doping type and the second layer of semiconductor material doped according to the first doping type and lightly doped compared to the first layer,
partially etching the second layer of semiconductor material, so as to obtain an island,
porosifying the layer of semiconductor material doped according to the first doping type, to obtain the porous first layer of semiconductor material, selectively epitaxially forming the zone comprising the one or more quantum wells on a first region of the island, and
selectively epitaxially forming the third layer of semiconductor material on the zone comprising the one or more quantum wells in the first region, so as to form the photoelectric transducer in the first region.

17. The method according to claim 16, wherein:
the step of selectively epitaxially forming the zone comprising the one or more quantum wells is performed simultaneously on a second region of the island, distinct from the first region, and
the step of selectively epitaxially forming the third layer of semiconductor material is performed simultaneously in the second region of the island so as to form the second photoelectric transducer in the second region of the island.

18. The method according to claim 17, further comprising forming:
a first electrode in electrical contact with the first portion of the third layer and belonging to the photoelectric transducer,
a second electrode in electrical contact with the second layer, the second electrode optionally being common to the photoelectric transducer and to the second photoelectric transducer;
a third electrode in contact with the third portion of the third layer and belonging to the second photoelectric transducer.

19. A method for integrating an optoelectronic system according to claim 11 with a control circuit, the method comprising:
forming a stack by successively epitaxially growing, on a substrate, a layer of semiconductor material doped according to the first doping type, the second layer, the zone comprising the one or more quantum wells, and the third layer of semiconductor material,
porosifying the layer of semiconductor material doped according to the first doping type, to obtain the porous first layer of semiconductor material, partially etching at least the third layer, to delimit the waveguide and obtain a first patterned zone and a second patterned zone, the first patterned zone and the second patterned zone being disposed on either side of the waveguide,
depositing a dielectric layer onto the waveguide;
depositing a first metal layer onto the dielectric layer and the third layer in the first patterned zone and the second patterned zone,
depositing a second metal layer onto a first face of a receiving substrate, the receiving substrate comprising the control circuit,
bonding the first metal layer and the second metal layer,
removing the substrate,
partially etching the first patterned zone so as to delimit the photoelectric transducer and of the second patterned zone so as to delimit the second photoelectric transducer,
forming:
a first electrode on the first portion of the second layer,
a second electrode on the third portion of the second layer,
a third metal layer on a second opposite face of the receiving substrate, the third metal layer being connected to the second metal layer forming a third electrode common to the photoelectric transducer and the second photoelectric transducer.

20. A method for integrating an optoelectronic system with a control circuit, the method comprising:
manufacturing the optoelectronic system according to claim 11;
forming on the stack a hybrid bonding tier comprising a first electrode in electrical contact with the first portion of the third layer, the first electrode belonging to the photoelectric transducer, and a second electrode in electrical contact with the third portion of the third layer, the second electrode belonging to the second photoelectric transducer, the first and second electrodes being surrounded by a dielectric layer, so as to obtain a planar surface with the first and second electrodes;
hybridly bonding the stack with a receiving substrate comprising the control circuit, the control circuit including a plurality of connection pads surrounded by a dielectric layer, so that the first electrode and the second electrode are bonded to the connection pads of the control circuit, and so that the dielectric layer of the stack is bonded to the dielectric layer of the control circuit,
removing the substrate,
partially etching:
within the photoelectric transducer: from the first portion of the porous first layer to the second layer, to obtain a first aperture,
within the second photoelectric transducer: from the third portion of the porous first layer to the second layer, to obtain a second aperture;
forming a third electrode in the first and second apertures, the third electrode being common to the photoelectric transducer and the second photoelectric transducer, and connecting the third electrode to one of the connection pads of the control circuit.
